(19) United States
(12) Patent Application Publication
(10) Pub. No.: US 2004/0255841 A1
(43) Pub. Date: Dec. 23, 2004

(54) Method for producing photonic crystal, and photonic crystal

(75) Inventors: Yasushi Enokido, Chiba-shi (JP); Hiroyasu Tsuchiya, Yuri-gun (JP)

Correspondence Address: STEVEN J WEISSBURG, 238 MAIN STREET, SUITE 303, CAMBRIDGE, MA, 02142

(73) Assignee: Massachusetts Institute of Technology, Cambridge, MA

(21) Appl. No.: 10/601,001

(22) Filed: Jun. 20, 2003

(51) Int. Cl. C30B 1/00

(52) U.S. Cl. 117/2

(57) ABSTRACT

Layers of slurry of dielectric powder are deposited one after another on a substrate through jet print technology to constitute a shaped article of dielectric layers. A predetermined region of the shaped article is bound with a binder to construct a photonic crystal having a three-dimensional structure. The jet print technology is free from limitation on the materials to be used therein, and broadens the configuration latitude in the photonic crystal produced. Photonic crystals having a controlled dielectric constant are easy to obtain through the technology.

### BACKGROUND

1. Field

The present invention relates to a method for producing a photonic crystal and the photonic crystal produced according to the method, especially to those for which is employed a slurry-based 3DP (three-dimensional printing) process proposed by the Massachusetts Institute of Technology.

2. Related Art

A photonic crystal, a structure of which the dielectric constant is two-dimensionally or three-dimensionally periodically changed, has now received much attention in the art. Regarding its dielectric constant, a photonic crystal having a two-dimensional periodic structure is hereinafter referred to as “two-dimensional photonic crystal”, and that having a three-dimensional periodic structure is as “three-dimensional photonic crystal”.

Such a photonic crystal has a periodic structure of two different types of dielectrics, and when electromagnetic waves enter it to cause Bragg diffraction, two standing waves form therein. One of the two standing waves is a high-energy standing wave to form in the low-dielectric-constant region of the photonic crystal, and the other is a low-energy standing wave to form in the high-dielectric-constant region thereof. Any intermediate-energy wave that falls between the two standing waves could not exist in the photonic crystal, which therefore has a photonic band gap therein. Electromagnetic waves falling within the energy wavelength range of the photonic band gap could not pass through the photonic crystal. Regarding its phenomenon as above, the photonic band gap referred to herein is considered the same as the band gap (forbidden band) of the electron energy level in the crystal.

Based on that phenomenon, electromagnetic waves may be trapped in dielectrics to thereby control their spatial propagation, and, for example, filters and optical waveguides may be small-sized.

FIG. 9 is a perspective view showing a woodpile structure known as one example of three-dimensional photonic crystals. Basically, this comprises dielectric bars 71 aligned in the direction of an X-axis at half-wavelength intervals relative to the wavelength of electromagnetic waves, and those aligned in the direction of a Y-axis also at half-wavelength intervals, and these dielectric bars 71 thus aligned in the two directions are alternately piled up in the direction of a Z-axis so that they cross perpendicularly to each other. In this, the dielectric bars 71 that are aligned in the same direction are piled up in the Z-axis direction with every bar being shifted from the neighboring one by a half period thereof.

FIG. 10 is a perspective view showing a Yablonovite structure also known as another example of three-dimensional photonic crystals. Basically, this comprises a dielectric block 81 having holes formed therein at predetermined triangular intervals with every opening 82 thereof being formed at intervals of 120° in three directions each at an angle of 35.26° relative to the normal line of each hole. In FIG. 10, reference numerals 82a to 82c indicate the direction of each hole.

For forming photonic crystal structures that have such a complicated three-dimensional configuration and for making them have a photonic band gap relative to the electromagnetic waves that enter them, at least two different types of dielectrics each having a different dielectric constant must be periodically arrayed at intervals that correspond to the wavelength of electromagnetic waves. For this, the periodic structure of the constitutive dielectrics must be accurately controlled at least on the wavelength of electromagnetic waves. To attain it, some methods have heretofore been investigated, including, for example, a dry-etching method, a self-cloning method and a photo-molding method.

The dry-etching method comprises forming a mask through photolithography followed by etching a material through the mask with an etching gas into a desired shape. The self-cloning method comprises bias-sputtering a material in a specific mode to thereby deposit the thus-sputtered material onto a substrate in the direction perpendicular to the substrate with the periodic irregularities of the surface of the substrate kept as such. The photo-molding method comprises exposing a liquid photocurable resin to scanning UV beams to thereby polymerize and cure the resin into a desired shape only in the UV-exposed region thereof.

However, the dry-etching method is problematic in that the material applicable to it is limited. The self-cloning method is also problematic in that the material applicable to it is limited. Another problem with it is that some desired defects are difficult to introduce into a part of the periodic structure formed in the method. Therefore, optical waveguides and other complicated devices are difficult to fabricate in the method. The photo-molding method is also problematic in that the material applicable to it is limited to photocurable resins only, and the electromagnetic wave transmission loss through the resins is great.

One object of the present invention is to provide a method for producing a photonic crystal of which the latitude in selecting the dielectric material to be used therein and in determining the shape of the photonic crystal to be produced therein is not limited at all. Another object of the invention is to provide a photonic crystal of which the structure and the dielectric constant can be controlled in any desired manner.

### SUMMARY

An invention provides a method for producing a photonic crystal made by periodically aligning a first dielectric and a second dielectric of which the relative dielectric constant differs from that of the first dielectric, and the method comprises a slurry-depositing step of continuously jetting out a slurry of a dielectric powder to give the first dielectric through a jet printhead onto a substrate to thereby deposit a dielectric layer thereon, a slurry-drying step of removing the solvent of the slurry from the dielectric layer, a binder-printing step of jetting out a binder through a jet printhead onto a predetermined part of the dielectric layer from which the solvent of the slurry has been removed to thereby infiltrate the binder into the predetermined region of the dielectric layer, a binder-drying step of removing the solvent of the binder having penetrated into the predetermined region of the dielectric layer to thereby bind the dielectric powder with the binder that exists in the predetermined region of the layer, and a powder-removing step of removing the dielectric powder not bound with the binder in the other region of the dielectric layer to thereby form a region in which the second dielectric is to be disposed.

In a method of the invention for producing the photonic crystal, the slurry-depositing step, the slurry-drying step, as well as the binder-printing step and the binder-drying step may be repeated predetermined times, and then the powder-removing step may be effected. Through the series of these steps, the part of the layer from which the dielectric powder has been removed forms a space and the other part thereof forms shaped blocks of dielectric powder aggregate.

A method of the invention for producing the photonic crystal may further comprise a binder-curing step of curing the binder having been infiltrated into the predetermined region of the dielectric layer in the binder-printing step.

In a method of the invention for producing the photonic crystal, the powder-removing step may be followed by a firing step of firing the region of the dielectric layer in which the second dielectric is to be disposed.

An invention also provides a method for producing a photonic crystal made by periodically aligning a first dielectric and a second dielectric of which the relative dielectric constant differs from that of the first dielectric, and the method comprises a slurry-depositing step that includes a first depositing step of jetting out a first slurry of a first dielectric powder to give the first dielectric through a jet printhead onto a predetermined part of a substrate to thereby form a first dielectric layer in that part and a second depositing step of jetting out a second slurry of a second dielectric powder to give the second dielectric through a jet printhead onto the other part of the substrate not deposited with the first slurry to thereby form a second dielectric layer in the other part of the substrate, a slurry-drying step of removing the solvent of the first and second slurries from the first and second dielectric layers, a binder-printing step of jetting out a binder through a jet printhead onto a predetermined part of the first and second dielectric layers from which the solvent has been removed to thereby infiltrate the binder into the predetermined regions of the first and second dielectric layers, and a binder-drying step of removing the solvent of the binder having penetrated into the predetermined regions of the dielectric layers to thereby separately bind the first and second dielectric powders with the binder that exists in the predetermined regions of the layers.

In a method of an invention for producing the photonic crystal, the slurry-depositing step, the slurry-drying step, as well as the binder-printing step and the binder-drying step may be repeated predetermined times. The series of these steps gives the intended photonic crystal that comprises periodically-aligned, first dielectric blocks of the first dielectric powder and second dielectric blocks of the second dielectric powder.

A method of an invention for producing the photonic crystal may further comprise a binder-curing step of curing the binder having been infiltrated into the predetermined regions of the dielectric layers in the binder-printing step.

In a method of an invention for producing the photonic crystal, the binder-curing step may be followed by a firing step of firing the first and second dielectric layers.

An invention further provides a photonic crystal made by periodically aligning a first dielectric and a second dielectric of which the relative dielectric constant differs from that of the first dielectric, in which at least one of the first and second dielectrics is formed of a shaped body of dielectric powder and its relative density falls between 48% and 63%.

In a photonic crystal of an invention, at least one of the first and second dielectrics may have a relative dielectric constant of from 3 to 100, preferably from 4.2 to 95.

In a photonic crystal of an invention, the ratio of the relative dielectric constant of the first dielectric to that of the second dielectric may fall between 5/7 and 1/100, preferably between 4.7/7.3 and 1/75.

In a photonic crystal of an invention, the periodic cycle of aligning the second dielectric in the first dielectric may fall between 0.1 mm and 10 mm.

In a photonic crystal of an invention, at least one of the first and second dielectrics may be formed by firing the shaped body.

In a photonic crystal and a method for producing it of the invention described hereinabove, at least one of the first and second dielectrics may be a BaO—TiO₂ material or an Al₂O₃ material. In these, one of the first and second dielectrics may be air.

According to a method for producing a photonic crystal of an invention, dielectric slurries may be deposited one by one through jet print technology to form predetermined patterns on a substrate, and the method enables the formation of a high-density and accurate structure with a complicated three-dimensional configuration that could not be realized through ordinary mechanical working. With no limitation thereon, the dielectric material for use in the invention may be any and every one capable of being in slurry. In the invention, therefore, dielectric materials of little loss can be selected and used, and dielectric materials having a different dielectric constant may be combined in any desired manner. Accordingly, any desired photonic crystal is easy to produce in the invention.

### BRIEF DESCRIPTION OF THE DRAWINGS

FIG. 1 is a flowchart showing the process of a first embodiment of an invention for producing a photonic crystal.

FIGS. 2A to 2F are side views schematically showing the process of a first embodiment of an invention for producing a photonic crystal.

FIG. 3 is a perspective view schematically showing the outline of a photonic crystal of a first embodiment of an invention.

FIG. 4 is a perspective view showing the constitution of a bend waveguide fabricated according to a slurry-based 3DP process of a first embodiment of an invention.

FIG. 5 is a flowchart showing the process of a second embodiment of an invention for producing a photonic crystal.

FIGS. 6A to 6D are side views schematically showing the process of a second embodiment of an invention for producing a photonic crystal.

FIG. 7 is a block view showing the outline constitution of a printhead favorable for an invention hereof.

FIG. 8 is a cross-sectional view showing the constitution of a continuous printhead favorable for an invention hereof.

FIG. 9 is a perspective view showing a basic constitution of a woodpile structure.

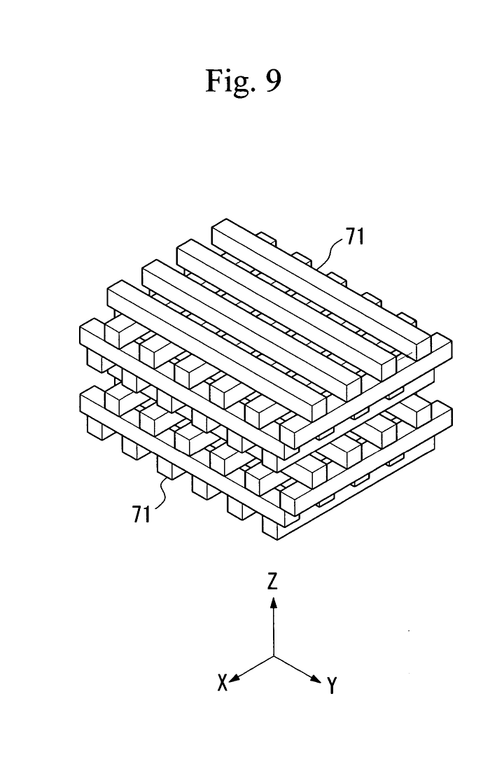

FIG. 10 is a perspective view showing a basic constitution of a Yablonovite structure.

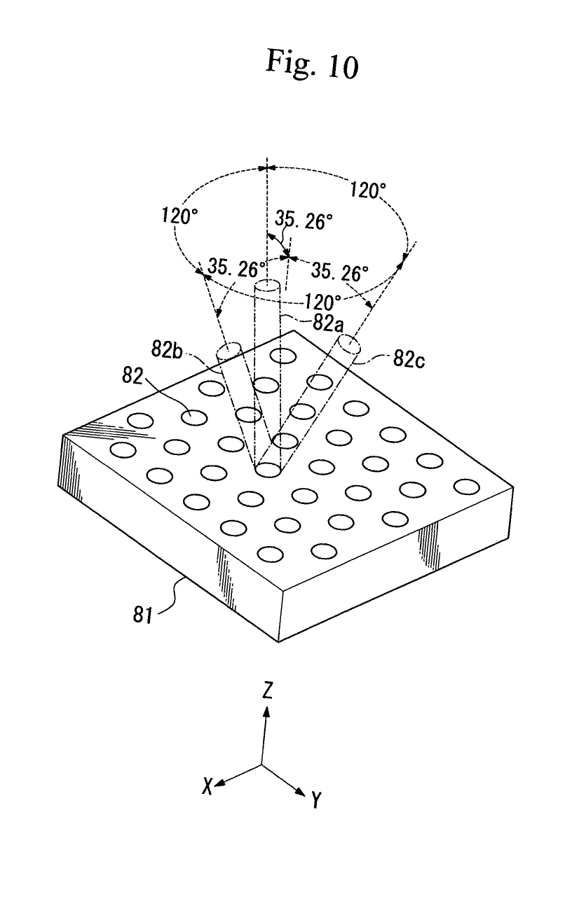

### DETAILED DESCRIPTION

Preferred embodiments of a method for producing a photonic crystal of an invention hereof and a photonic crystal produced according to the method are described hereinunder with reference to the drawings.

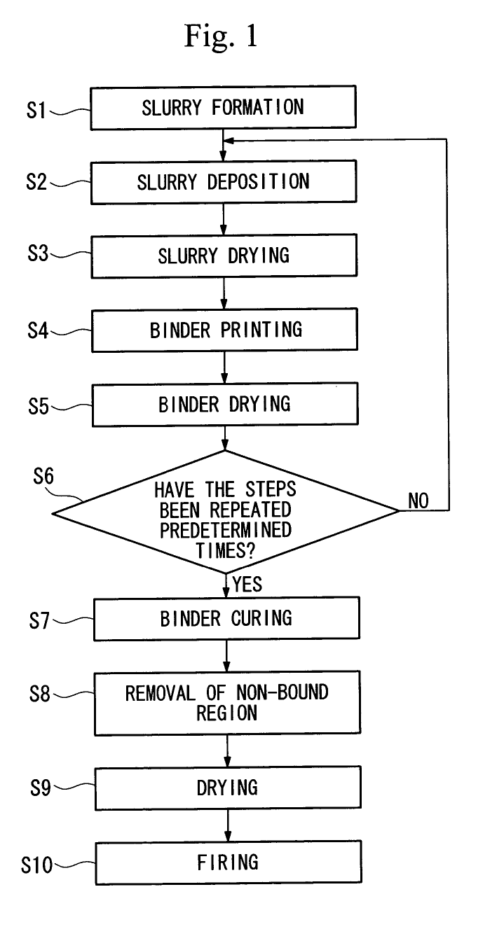

FIG. 1 is a flowchart to explain the basic process of a first embodiment of an invention for producing a photonic crystal. The process of the flowchart is referred to as “slurry-based 3DP process”. The material employable in the slurry-based 3DP process may be any and every one capable of being in slurry, and there is no limitation on material selection for the process. For example, not only ceramics such as alumina (Al₂O₃), silicon carbide (SiC) and barium titanate (BaTiO₃) but also plastics such as acryl and polycarbonate, metals such as Al, Cu and Ag, and semiconductors such as Si and GaAs are all employable in the process. Slurry based Three Dimensional Printing processes are described in detail in co-assigned, U.S. allowed application, U.S. Ser. No. 09/445,670, entitled JETTING LAYERS OF POWDER AND THE FORMATION OF FINE POWDER BEDS THEREBY, in the names of inventors Emanuel M. Sachs et al., 35 U.S.C. 102(e) date Mar. 1, 2000, which was the U.S. National Phase of PCT/US98/12280, filed Jun. 12, 1998, and published on Dec. 17, 1998, the full disclosure of which is hereby fully incorporated by reference herein.

In the slurry-based 3DP process, a dielectric powder to form a photonic crystal is first dispersed in a solvent to give a slurry in the slurry-forming step S1. The solvent may be an organic solvent such as alcohol, but is preferably a water-based solvent since it is not toxic and is easy to handle and since it has few influences on the dielectric powder. If desired, a dispersant may be added to the solvent. In case where two or more different types of dielectrics are used to form a photonic crystal, the respective dielectric powders are separately formed into slurries.

In the next slurry-depositing step S2, the slurry of the dielectric powder is deposited in a mode of jet printing on the surface of a substrate to form one layer thereon. The thickness of the dielectric layer to be formed shall be determined in consideration of the degree of shrinkage of the layer in the subsequent drying step. The jet print process will be described hereinunder.

In the next slurry-drying step S3, the solvent is removed from the dielectric layer formed in the slurry-depositing step S2, by drying the layer. For example, the layer may be spontaneously dried or may be dried under heat.

In the next binder-printing step S4, a binder is applied onto a predetermined part of the dielectric layer in a mode of jet printing. The part to which the binder is applied is the area to form the three-dimensional periodic structure of the photonic crystal to be produced. The amount of the binder jet shall be so controlled that the binder may reach the depth of one dielectric layer.

The type of the binder to be used in the binder-printing and step S4 is not specifically defined, but is preferably a water-soluble binder that requires water for its solvent. This is because such a water-soluble binder is easy to handle and is not toxic and it has few influences on the dielectric powder. After it has cured, the binder must be insoluble in water. This is because the dielectric powder not cured with the binder must be re-dispersed in water and removed from the shaped dielectric body (in the subsequent step S8). In view of the mechanical strength thereof after being cured, the binder is preferably a thermosetting resin, more preferably polyacrylic acid (PPA).

In the next binder-drying step S5, the solvent of the binder having penetrated into the dielectric layer is removed by drying the layer. For example, the layer may be spontaneously dried or may be dried under heat. After having been processed in the binder-drying step S5, the dielectric powder existing in the region of the dielectric layer into which the binder has penetrated is bound with the binder. The steps from the slurry-depositing step S2 to the binder-drying step S5 are repeated predetermined times (as in the inspection step S6 in FIG. 1). With that, formed are shaped blocks that comprise a region in which the dielectric powder has been bound with the binder (bound region) and a region in which the powder is not bound (non-bound region). For example, the bound region forms a first dielectric and the non-bound region forms a second dielectric. The details will be described below. In the binder-printing step S4, the binder is applied to the dielectric layer in such a controlled manner that the two regions, bound region and non-bound region are alternately aligned.

After the above-mentioned steps have been repeated predetermined times, the thus-processed dielectric layer then undergoes the next binder-curing step S7.

In the binder-curing step S7, the shaped body of a predetermined number of dielectric layers that have been formed through repetition of the previous steps is heat-treated whereby the binder having penetrated into each dielectric layer in the binder-printing step S4 is fully cured. Through the treatment, the dielectric powder is more firmly bound with the cured binder, and, as a result, the mechanical strength of the resulting three-dimensional dielectric structure is increased to thereby make it easier to handle the structure in the subsequent steps.

The binder-curing step S7 is followed by the next removing step S8.

In the removing step S8, the dielectric powder existing in the non-bound region is removed from the shaped body. For example, the shaped body of multiple dielectric layers that have been deposited one after another on a substrate is dipped in water to remove the dielectric powder from it. In other words, when the shaped body is dipped in water, the dielectric powder not bound with the binder therein removes from each dielectric layer and disperse in water. This treatment is referred to as re-dispersion.

In order that the dielectric powder not bound with the binder is readily re-dispersed in water in the removing step S8, it is desirable that a dispersant is previously added to the slurry formed in the slurry-forming step S1. For the dispersant, for example, employable is polyethylene glycol (PEG). For effective re-dispersion, ultrasonic waves are applied to water in which the shaped body is dipped, or directly to the shaped body.

After the removing step, the shaped body in which the dielectric powder has been three-dimensionally bound with the binder is drawn up from water, and then this undergoes the next drying step S9. For example, the shaped body is spontaneously dried or dried under heat like in the previous steps.

After the drying step S9, the shaped body may directly serve as a photonic crystal, but if desired, it may be fired into a sintered body in the next firing step 10. The sintered body is better than the dried shaped body in point of the mechanical strength and the dielectric constant.

In the above process, the binder-curing step S7 is followed by the removing step S8. However, depending on the density of the dielectric powder in the region with the binder penetrated thereinto and on the property of the binder used, the binder-curing step S7 may be omitted, or that is, the binder-drying step may be directly followed by the subsequent removing step S8. Naturally, an invention shall encompasses this embodiment not requiring the binder-curing step S7.

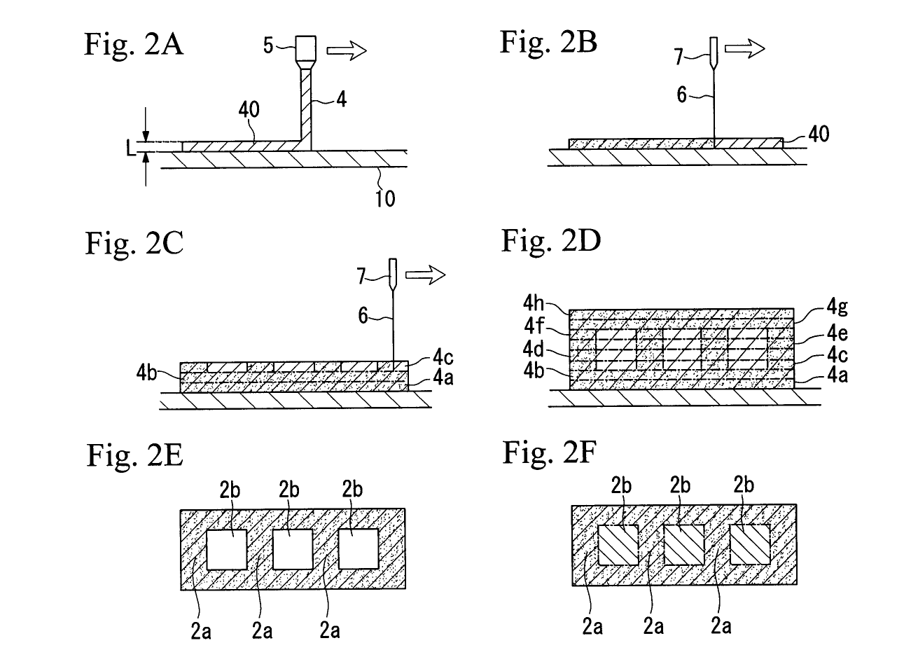

The steps that constitute a first embodiment of a method for producing a photonic crystal of an invention are described hereinunder with reference to FIG. 2 that shows one example the constitution of a photonic crystal.

FIG. 2A schematically shows a mode of forming a first dielectric layer on a substrate 10 by jetting out a slurry of dielectric powder through a jet printhead in the slurry-depositing step S2.

With the jet printhead 5 for jetting out slurry being two-dimensionally scanned, the slurry 4 of dielectric powder is continuously jetted out toward the substrate 10 and is deposited on the entire surface of the substrate 10. In FIG. 2A, the jet printhead is movable. Different from the illustrated case, the head may be fixed and the substrate 10 may be moved.

In case where the substrate 10 is porous, it may absorb the solvent in the deposited dielectric layer to increase the degree of dielectric powder aggregation, and the shaped density of the dielectric powder may be thereby increased. For this purpose, sintered alumina or the like may be used for the substrate 10. As the case may be, a shaped body of dielectric powder to form the slurry may be the substrate 10.

When the solvent in the slurry is dried up and removed in the slurry-drying step S3, one dielectric layer 4a having a thickness of L is formed.

After the first dielectric layer 4a has been thus formed, it undergoes the next binder-printing step S4 as in FIG. 2B.

FIG. 2B schematically shows the binder-printing step S4 in which a binder 6 is jetted out through a jet printhead 7 onto a predetermined area of the layer 4a.

With the jet printhead 7 for jetting out binder being scanned, the binder 6 is continuously jetted out toward the deposited dielectric layer 4a and is infiltrated into the entire surface of the layer 4a. In FIG. 2, the region having received the binder 6 is shaded. The amount of the binder 6 to be jetted out through the jet printhead 7 is so controlled that the binder 6 fully reaches the entire region of the dielectric layer 4a. After the binder 6 has been thus printed and deposited thereon, the thus-processed substrate then undergoes the next binder-drying step S5 of drying up and removing the binder 6.

After the binder-drying step S5 as in FIG. 2B, a slurry 4 to form a second dielectric layer is deposited, then a binder 6 for the second dielectric layer 2b is deposited, and thereafter a slurry 4 to form a third dielectric layer is deposited in the same manner as previously. After the slurry 4 to form the third dielectric layer has been deposited and the solvent has been removed from the slurry 4, a binder 6 is further printed thereon. FIG. 2C shows this process. As in FIG. 2C, the binder 6 is intermittently jetted out while the jet printhead is scanned. In FIG. 2C, the binder 6 is not jetted out onto the white blank region of the dielectric layer 4c. Accordingly, the binder 6 does not penetrate into the white blank region of the layer 4c.

Like in FIG. 2C, a binder 6 is also intermittently deposited to form the fourth to sixth dielectric layers 4d to 4f. On the other hand, the seventh and eighth dielectric layers 4g and 4g receive the binder 6 in their entire region as in FIG. 2B. In this process, the solvent in the slurry and the binder 6 is appropriately removed. FIG. 2D shows the thus-fabricated shaped body.

As in FIG. 2D, the shaped body includes a region with the binder 6 therein and a region with no binder therein that are periodically aligned. The shaped body of FIG. 2D then undergoes the next binder-curing step S7. In this step, the shaped body is heat-treated to thereby cure the binder 6 having penetrated thereinto.

FIG. 2E schematically shows the shaped body of FIG. 2D from which the dielectric powder having existed in the region not cured with the binder 6 has been removed. After the binder-curing step S7, the shaped body is dipped in water. Thus dipped in water, the dielectric powder existing in the region of the shaped body not cured with the binder 6 is re-dispersed in water and removed from the shaped body. The region from which the dielectric powder has been removed forms a space with air therein. Through the operation, the substrate 10 is released from the shaped body. In this step, it is effective to apply ultrasonic waves to the shaped body being processed. The region of the shaped body from which the dielectric powder has been removed forms a space. Accordingly, the shaped body is a three-dimensional photonic crystal structure, which comprises a first dielectric 2a with dielectric powder therein and a second dielectric 2b with air therein that are periodically aligned. As so mentioned hereinabove, the structure may be further fired.

The shaped body of FIG. 2E is a photonic crystal in which the second dielectric is air. Apart from this, any other photonic crystal in which the second dielectric is not air but is formed of any other dielectric substance may also be fabricated in the same manner as herein.

FIG. 2F shows a different embodiment of a shaped body or a sintered body of FIG. 2E in which the first dielectric is formed of a dielectric slurry in the same manner as above and thereafter the space for the second dielectric is filled with a different dielectric substance to be a second dielectric 2c. In this embodiment, the difference in the dielectric constant between the first dielectric 2a and the second dielectric 2c may be determined in accordance with the intended property of the photonic crystal to be produced.

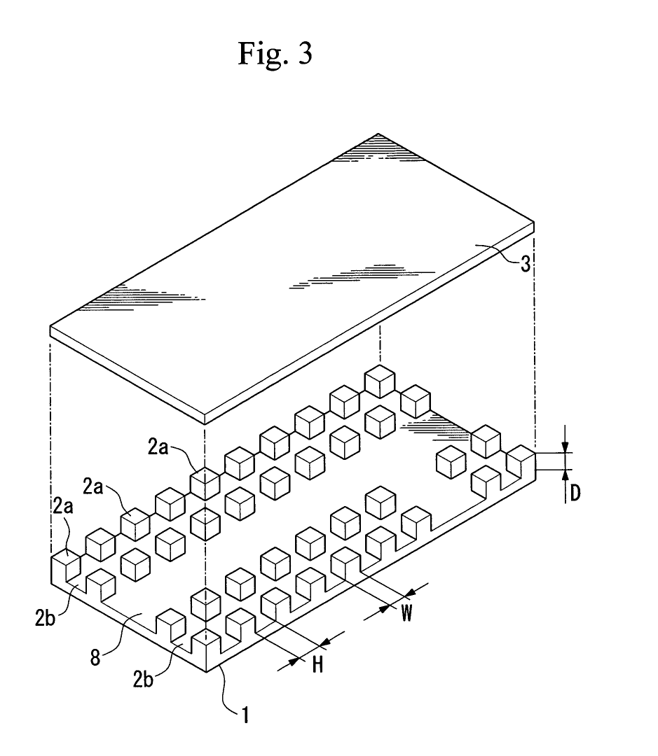

FIG. 3 is a perspective view schematically showing one example of a photonic crystal of an invention which can be produced according to a production method mentioned above.

As in FIG. 3, the lower substrate 1 made of a first dielectric has pillars 2a of the same dielectric as that of the substrate 1, and the dielectric pillars 2a are periodically aligned. Above the pillars 2a, disposed is an upper substrate 3 of the same dielectric as that of the pillars 2a. In FIG. 3, the upper substrate 3 is spaced from the lower substrate 1 and the pillars 2a for easy understanding of the inner constitution of the structure illustrated. In fact, however, the lower substrate 1, the pillars 2a and the upper substrate 3 are integrated together. In the photonic crystal illustrated, the air 2b in the region surrounded by the lower substrate 1, the pillars 2a and the upper substrate 3 serves as the second dielectric. The photonic crystal has a waveguide 8 formed therein.

Every part of the first dielectric is formed of dielectric powder according to the slurry-based 3DP process mentioned hereinunder. Its relative density falls between 48 and 65%, preferably between 55 and 63%.

In the photonic crystal illustrated, the height of each pillar 2a is D, the width thereof is W and the space between the neighboring pillars 2a is H. In that condition, the periodic cycle, T (T=H+W) of aligning the pillars 2a must be T=0.5λ or so, or that is, the periodic cycle of the pillars 2a in the photonic crystal must be about a half of the wavelength of the electromagnetic wave that enters the photonic crystal, in order that the photonic crystal may express a photonic band gap relative to the incident electromagnetic wave having a wavelength of λ. The width, W, of each pillar 2a, or that is, the periodic cycle of aligning the second dielectric in the first dielectric falls between 0.1 and 10 mm.

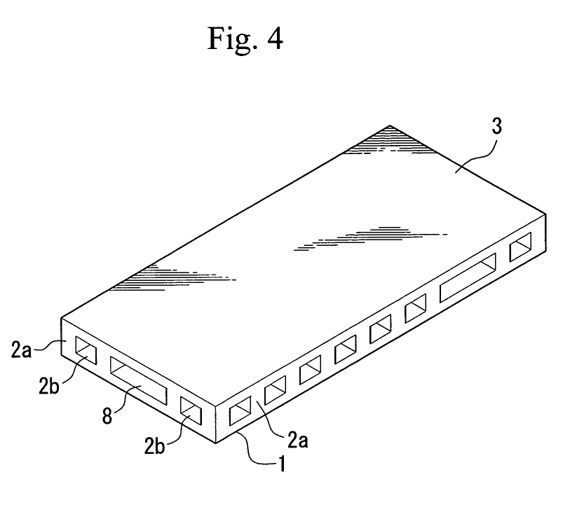

FIG. 4 is an outline view showing a bend waveguide for which the lower substrate 1, the pillars 2a and the upper substrate 3 shown in FIG. 3 are integrated together. The bend waveguide is one example of a photonic crystal fabricated according to a production method of an invention hereof, or that is, fabricated according to the slurry-based 3DP process for a region of from milli-level waves to submilli-level waves.

For the dielectric substances, used are alumina (having a relative dielectric constant ∈, 10.44) and a barium titanate ceramic (having a relative dielectric constant ∈, 95). The former is available from Ceralox® (a division of Sasol North America, Inc. of Tuscon, Ariz.). The latter is available from TDK (Tokyo, Japan) and its composition is BaO—Nd₂O₃—TiO₂—B₂O₃—ZnO₂—CuO.

Each dielectric powder is dispersed in a solvent to give a slurry. The solvent used is a mixture of water and methanol. The particle size of the dielectric powders falls between 0.5 and 2.0 μm or so. A dispersant, available from Toa Gosei Co., Ltd. of Tokyo, Japan, A-30SL, under the product code, is used in forming the dielectric slurries.

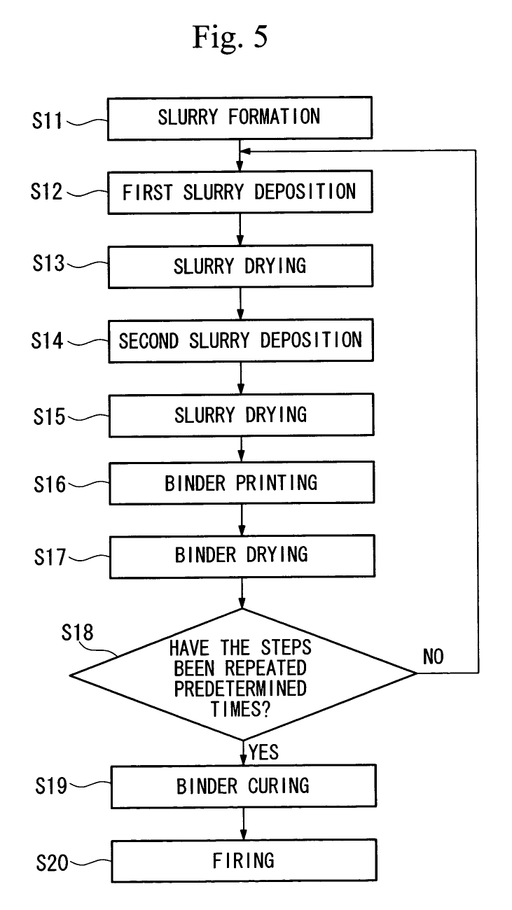

The bend waveguide of FIG. 5 is usable at around 90 GHz. Regarding the dimension of the shaped body of the dielectric powder, the pitch, H =W =1 mm (that is, the periodic cycle is 2 mm), the overall size is 16 mm×9 mm and the height is 2.5 mm. When fired, this shrinks to about 85%.

In a slurry-depositing step, a slurry is jetted out toward the substrate through a jet printhead having a nozzle diameter of 128 μm, and deposited thereon to form one layer having a dry thickness of from 25 to 75 μm or so. The slurry layer is dried at about 80° C. for 30 seconds. Onto a predetermined site of the thus-formed dielectric layer, a binder is jetted out through a jet printhead having a nozzle diameter of from 30 to 75 μm, and printed thereon. Thus printed, the binder penetrates into the dielectric layer to bind the dielectric powder existing in the predetermined region of the layer. The binder is cured through heat treatment at 150° C. for 1 hour. In this step, it is desirable that the curing treatment is effected in a non-oxidative atmosphere such as argon for preventing the re-dispersant from being degraded.

With the binder having penetrated into the predetermined region of the dielectric layer, the dielectric powder in the layer is three-dimensionally bound to give a shaped body, which is then further heat-treated to fully cure the binder. Thus processed, the dielectric layer is re-dispersed in water to thereby remove the dielectric powder not bound with the binder from the layer. The process gives the intended photonic crystal structure.

In case where ceramics having a high dielectric constant for milli-level waves to submilli-level waves are used, their particle size preferably falls between 0.1 and 5.0 μm, more preferably between 0.5 and 2.0 μm. The ceramics of the type enable high-density shaping and prevent powder aggregation, and the periodic structure of the shaped body formed is stabilized.

Ceramics favorable for fabricating photonic crystals for use in milli-level wave bands have a dielectric constant of from 3 to 100, include barium titanate, alumina and glass.

Next described is a second embodiment of an invention for producing a photonic crystal through jet printing with two different types of slurries. In this discussion of the second embodiment, describing the matters common to both the first and second embodiments is omitted.

FIG. 5 is a flowchart for explaining the second embodiment of the invention for producing a photonic crystal.

In the first slurry-forming step S11, a first dielectric powder to form a first dielectric of a photonic crystal and a second dielectric powder to form a second dielectric thereof are separately dispersed in a solvent to prepare a first slurry and a second slurry.

In the subsequent slurry-depositing steps S12 and S14, the first slurry and the second slurry are separately jet out and deposited on a substrate to form thereon one first layer and one second layer, respectively. For example, the first slurry is jetted out through a first jet printhead, and deposited in a predetermined region. Then, the thus-deposited layer is optionally dried in the step S13, and thereafter the second slurry is jetted out through a second jet printhead and deposited in the other region not having the first slurry deposited therein. This is the second slurry-depositing step S14. Needless-to-say, the two jet printheads may be simultaneously driven to deposit the two, first and second layers at the same time.

In the next slurry-drying step S15, the dielectric layers deposited in the slurry-depositing steps S12 and S14 are dried to remove the solvent from them.

The steps including the slurry-depositing step S12 to the slurry-drying step S15 are repeated predetermined times. After these steps have been repeated predetermined times, the thus-processed dielectric layers then undergo the next binder-printing step S17 (after the inspection step S16).

In the next binder-printing step S17, a binder is printed on the predetermined region of the shape body in which a predetermined number of the first and second dielectric layers have been deposited on the substrate. Thus printed, the binder penetrates into the predetermined region of the shaped body. With that, the solvent in the thus-infiltrated binder is dried up in the binder-drying step S18, and then the binder is cured in the next binder-curing step 19. In the binder-curing step S19, the shaped body is heat-treated to thereby cure the binder 6 having penetrated into the shaped body. The shaped body obtained after the binder-curing step 19 constitutes a photonic crystal in which the first dielectric and the second dielectric are periodically aligned.

If desired, the shaped body after the binder-curing step S19 may be fired in the next firing step S20 into a sintered body.

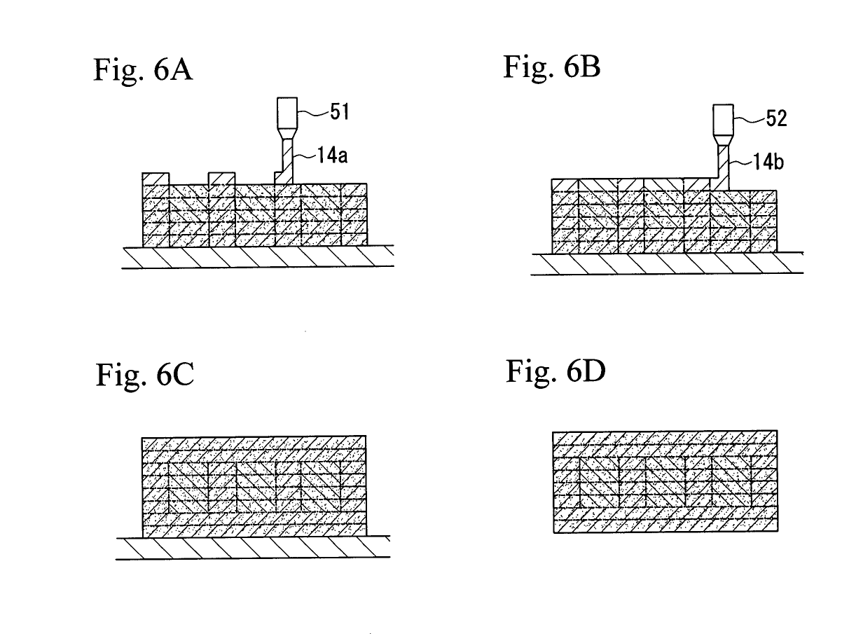

The steps that constitute a second embodiment of a method for producing a photonic crystal of an invention hereof are described hereinunder with reference to FIG. 6 that shows one example of the constitution of the photonic crystal.

FIG. 6A shows a mode of the first dielectric slurry-depositing step S12 of depositing one first dielectric layer on the substrate by intermittently jetting out a first slurry 14a toward the substrate through a jet printhead 51 for the first slurry. As in FIG. 6(a), five layers of the first slurry 14a and three layers of the second slurry 14b are deposited on the substrate, and then the first slurry 14a is again deposited on the five-layered first slurry. The jet printhead 51 is driven under on/off control so as to jet out the slurry onto only the predetermined site.

Thus deposited, the first slurry is dried in the drying step S13.

FIG. 6B shows a mode of the second dielectric slurry-depositing step S14 of depositing one additional second dielectric layer on the area not having the first slurry 14a therein, by intermittently jetting out an additional second slurry 14b toward that area through a jet printhead 52 for the second slurry. As in FIG. 6B, the additional second slurry 14b is deposited after the first slurry 14b has been deposited in the step of FIG. 6A. The jet printhead 52 is driven also under on/off control so as to jet out the second slurry 14b onto only the predetermined site. After the first slurry 14a and the second slurry 14b have been deposited, the solvent may be removed in any desired manner.

FIG. 6C schematically shows the shaped body comprising the first dielectric powder and the second dielectric powder, for which the above-mentioned steps are repeated predetermined times. This shaped body constitutes a photonic crystal having a three-dimensional structure.

If desired, a binder may be added to a part or all of the shaped body obtained in the above and may be thermally cured therein. In addition, after the solvent of the binder has been dried up, the shaped body may be fired. The dielectrics constituting the fired body are densified, and the mechanical strength and the dielectric constant of the photonic crystal of the fired body are increased.

Next described is a jet print apparatus for a slurry-based 3DP process that is favorable for a method of an invention hereof for producing a photonic crystal.

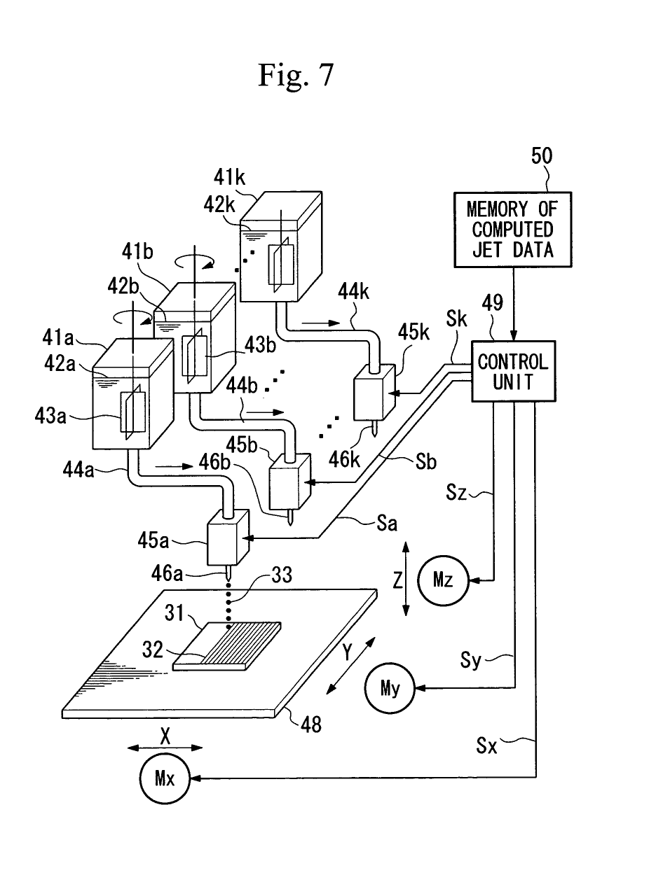

FIG. 7 is a block view showing one example of the constitution of a jet print apparatus for forming photonic crystals through jet printing. The apparatus comprises tanks 41a to 41k for pooling slurries of dielectric powder and binder therein; jet printheads 45a to 45k for jetting out slurry and binder therethrough; a table 48 that travels in the X-Y direction with a substrate 31 mounted thereon, on which a photonic crystal structure is to be deposited; and a control unit 49.

The tanks 41a to 41k are to temporarily pool therein slurries prepared by dispersing dielectric powder in a solvent and a binder for binding and curing the dielectric powder, and these are individually connected with the corresponding jet printheads 45a to 45k via connecting ducts 44a to 44k, respectively. The slurry tanks 41a to 41k are equipped with slurry-stirring stirrer 43a to 43k, respectively, with which the slurry in each tank is stirred so that the dielectric powder therein does not deposit in the tank. The slurries and the binder pooled in the tanks are fed to the corresponding jet printheads 45a to 45k, for example, by the action of air pressure applied thereto.

Through the jet printheads 45a to 45k, the slurries or the binder are jetted out to give predetermined patterns on the substrate 31. The heads 45a to 45k are equipped with nozzles 46a to 46k, respectively, via which fine drops 33 of each slurry or binder are jetted out onto the substrate 31. Regarding their type, the nozzles 46a to 46k of the jet printheads 45a to 45k may jet out the liquid drops 33 based on their thermal expansion caused by a heater equipped thereto. Preferably, however, they jet out the liquid drops 33 based on their volume change caused by a piezoelectric device fitted thereto.

Also preferably, the jet printheads 45a to 45k for jetting out slurry are continuous printheads through which slurry is continuously jetted out with no nozzle clogging trouble. However, they may also be drop-on-demand type printheads through which slurry is intermittently jetted out under on/off control. On the other hand, the jet printhead 45k for jetting out a binder 42k therethrough may be a drop-on-demand type printhead with no risk of nozzle clogging.

The control unit 49 is to control the jet printheads 45a to 45k and motors Mx, My and Mz, based on the memory of previously computed jet data 50. This transmits jet signals Sa to Sk and drive signals Sx, Sy and Sz to the jet printheads 45a to 45k and to the motors Mx, My and Mz, and these heads and motors are driven based on the signals thus transmitted to them. The details of the memory of the computed jet data 50 include the type and the jet amount of the slurry and the binder to be selected for every dot from every line for the individual layers of from the 1st to p'th layers to be formed.

On the table 48, mounted is the substrate 31. The table 48 may be slid in the X-axis direction and the Y-axis direction by the motors Mx and My. If desired, the table 48 may be moved up and down in the Z-axis direction by the motor Mz.

In the apparatus illustrated, the substrate 31 on the table 48 shall move relatively to the jet printheads 45a to 45k. Needless-to-say, therefore, the heads may be moved on the basis of the memory of the computed jet data 50 to give predetermined patterns on the substrate 31.

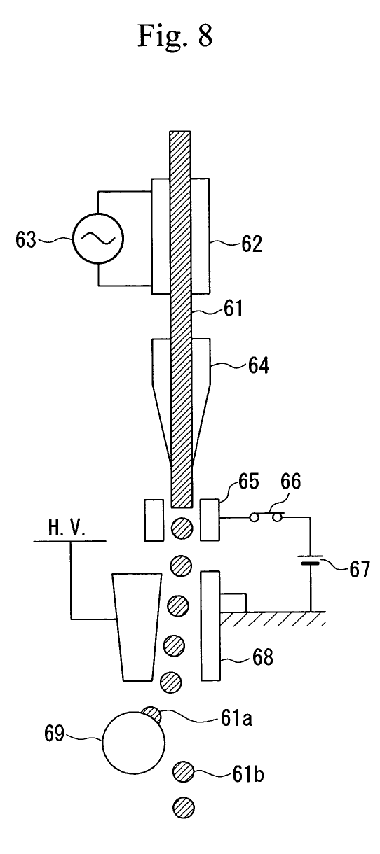

FIG. 8 is a cross-sectional view showing one example of the constitution of a continuous printhead favorable for the method for producing a photonic crystal of the invention.

The continuous printhead comprises a piezoelectric tube 62, a nozzle 64, a charging cell 65, a deflection cell 68 and a catcher 69 that are aligned in that order. A binder 61 pooled in a tank is extruded out of the binder tank by the action of air pressure applied thereto, and then fed to the nozzle 64 via the piezoelectric tube 62.

The piezoelectric tube 62 is driven by an AC voltage applied thereto from an AC power source 63, and it vibrates the binder passing through it. With the constitution, the piezoelectric tube 62 stabilizes the drops of the binder 61.

The charging cell 65 is to electrically charge the drops of the binder 61. From tens to hundreds of volts DC is applied to the charging cell 65 from a DC power source 67. With on/off control of the switch 66, the electric charge of the binder drops having entered the charging cell 65 is controlled. The binder drops of which the electric charge has been controlled by the charging cell than pass through the deflection cell 68.

The deflection cell 68 is to change the traveling direction of the binder drops of which the electric charge has been controlled by the charging cell 65. From hundreds to thousands of volts DC is applied to the deflection cell 68 from a high-voltage power source H.V.

When the binder drops 61a thus having been charged by the charging cell 65 enter the deflection cell 68, they are deflected by the electric field in the cell to go toward the catcher 69. The binder drops thus caught by the catcher 69 are discarded. On the other hand, the traveling direction of the binder drops 61b not charged by the charging cell 65 does not change even after they have entered the deflection cell 68, and therefore the binder drops 61b directly pass through the deflection cell 68 to reach the object to be printed with them.

The binder 61 having been led into the nozzle 64 drops down while forming in spheres, and it becomes binder drops. When the binder drops are thus formed while the binder 61 drops down through the nozzle 64, they enter the charging cell 65.

Thus, this document discloses many related inventions.

This disclosure describes and discloses more than one invention. The inventions are set forth in the claims of this and related documents, not only as filed, but also as developed during prosecution of any patent application based on this disclosure. The inventors intend to claim all of the various inventions to the limits permitted by the prior art, as it is subsequently determined to be. No feature described herein is essential to each invention disclosed herein. Thus, the inventors intend that no features described herein, but not claimed in any particular claim of any patent based on this disclosure, should be incorporated into any such claim.

Some assemblies of hardware, or groups of steps, are referred to herein as an invention. However, this is not an admission that any of such assemblies or groups are necessarily patentably distinct inventions, particularly as contemplated by laws and regulations regarding the number of inventions that will be examined in one patent application, or unity of invention. It is intended to be a short way of saying an embodiment of an invention.

An abstract is submitted herewith. It is emphasized that this abstract is being provided to comply with the rule requiring an abstract that will allow examiners and other searchers to quickly ascertain the subject matter of the technical disclosure. It is submitted with the understanding that it will not be used to interpret or limit the scope or meaning of the claims, as promised by the Patent Office's rule.

The foregoing discussion should be understood as illustrative and should not be considered to be limiting in any sense. While the inventions have been particularly shown and described with references to preferred embodiments thereof, it will be understood by those skilled in the art that various changes in form and details may be made therein without departing from the spirit and scope of the inventions as defined by the claims.

The corresponding structures, materials, acts and equivalents of all means or step plus function elements in the claims below are intended to include any structure, material, or acts for performing the functions in combination with other claimed elements as specifically claimed.

What is claimed is:

1. A method for producing a photonic crystal made by periodically aligning a first dielectric and a second dielectric of which the relative dielectric constant differs from that of the first dielectric, the method comprising:
a slurry-depositing step of continuously jetting out a slurry of a dielectric powder to give the first dielectric through a jet printhead onto a substrate to thereby deposit a dielectric layer thereon,
a slurry-drying step of removing solvent of the slurry from the dielectric layer,
a binder-printing step of jetting out a binder through a jet printhead onto a predetermined part of the dielectric layer from which the solvent of the slurry has been removed to thereby infiltrate the binder into the predetermined region of the dielectric layer,
a binder-drying step of removing solvent of the binder having penetrated into the predetermined region of the dielectric layer to thereby bind the dielectric powder with the binder that exists in the predetermined region of the layer, and
a powder-removing step of removing dielectric powder not bound with the binder in another region of the dielectric layer to thereby form a region in which the second dielectric is to be disposed.

2. The method for producing the photonic crystal as claimed in claim 1, wherein the slurry-depositing step, the slurry-drying step, as well as the binder-printing step and the binder-drying step are repeated predetermined times, and then the powder-removing step is effected to thereby form blocks of the first dielectric.

3. The method for producing the photonic crystal as claimed in claim 1, which further comprises a binder-curing step of curing the binder having been infiltrated into the predetermined region of the dielectric layer in the binder-printing step.

4. The method for producing the photonic crystal as claimed in claim 1, wherein at least one of the first and second dielectrics is a material selected from the group consisting of:
BaO—TiO₂ and Al₂O₃.

5. The method for producing the photonic crystal as claimed in claim 1, wherein one of the first and second dielectrics is air.

6. The method for producing the photonic crystal as claimed in claim 1, wherein the powder-removing step is followed by a firing step of firing the region of the dielectric layer in which the second dielectric is to be disposed.

7. A method for producing a photonic crystal made by periodically aligning a first dielectric and a second dielectric of which the relative dielectric constant differs from that of the first dielectric, the method comprising:
a slurry-depositing step that includes a first depositing step of jetting out a first slurry of a first dielectric powder to give the first dielectric through a jet printhead onto a predetermined part of a substrate to thereby form a first dielectric layer in that part and a second depositing step of jetting out a second slurry of a second dielectric powder to give the second dielectric through a jet printhead onto the other part of the substrate not having the first slurry therein to thereby form a second dielectric layer in the other part of the substrate,
a slurry-drying step of removing solvent of the first and second slurries from the first and second dielectric layers,
a binder-printing step of jetting out a binder through a jet printhead onto a predetermined part of the first and second dielectric layers from which the solvent has been removed to thereby infiltrate the binder into the predetermined regions of the first and second dielectric layers, and
a binder-drying step of removing solvent of the binder having penetrated into the predetermined regions of the dielectric layers to thereby separately bind the first and second dielectric powders with the binder that exists in the predetermined regions of the layers.

8. The method for producing the photonic crystal as claimed in claim 7, wherein the slurry-depositing step, the slurry-drying step, as well as the binder-printing step and the binder-drying step are repeated predetermined times.

9. The method for producing the photonic crystal as claimed in claim 7, which further comprises a binder-curing step of curing the binder having been infiltrated into the predetermined regions of the dielectric layers in the binder-printing step.

10. The method for producing the photonic crystal as claimed in claim 7, wherein at least one of the first and second dielectrics is a material selected from the group consisting of: BaO—TiO₂ and Al₂O₃.

11. The method for producing the photonic crystal as claimed in claim 7, wherein the binder-curing step is followed by a firing step of firing the first and second dielectric layers.

12. A photonic crystal made by periodically aligning a first dielectric and a second dielectric of which the relative dielectric constant differs from that of the first dielectric, wherein:
at least one of the first and second dielectrics is formed of a shaped body of dielectric powder and its relative density falls between 48% and 63%.

13. The photonic crystal as claimed in claim 12, wherein at least one of the first and second dielectrics has a relative dielectric constant of from 3 to 100.

14. The photonic crystal as claimed in claim 12, wherein the ratio of the relative dielectric constant of the first dielectric to that of the second dielectric falls between 4.7/7.3 and 1/100.

15. The photonic crystal as claimed in claim 12, wherein at least one of the first and second dielectrics is a material selected from the group consisting of: BaO—TiO₂ and Al₂O₃.

16. The photonic crystal as claimed in claim 12, wherein one of the first and second dielectrics is air.

17. The photonic crystal as claimed in claim 12, wherein the periodic cycle of aligning the second dielectric in the first dielectric falls between 0.1 mm and 10 mm.

18. The photonic crystal as claimed in claim 12, wherein at least one of the first and second dielectrics is formed by firing the shaped body.
